(19) United States
(12) Patent Application Publication
(10) Pub. No.: US 2011/0003168 A1
(43) Pub. Date: Jan. 6, 2011

(54) REFLECTIVE FILM AND SEMI-TRANSMISSIVE REFLECTIVE FILM OF OPTICAL INFORMATION RECORDING MEDIUM, SPUTTERING TARGET FOR MANUFACTURING THEM, AS WELL AS OPTICAL INFORMATION RECORDING MEDIUM

(75) Inventors: Norihiro Jiko, Hyogo (JP); Junichi Nakai, Hyogo (JP); Yuki Tauchi, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Kobe Seiko Sho (Kobe Steel Ltd.), Kobe-shi, Hyogo (JP)

(21) Appl. No.: 12/866,230

(22) PCT Filed: Feb. 5, 2009
(86) PCT No.: PCT/JP09/51999

§ 371 Date: Aug. 4, 2010

(30) Foreign Application Priority Data
Feb. 8, 2008 (JP) 2008-029116

(51) Int. Cl. B32B 3/00; C23C 14/34; C23C 14/14; C22C 5/06

(52) U.S. Cl. 428/606; 204/192.1; 204/298.13; 420/501

(57) ABSTRACT

The present invention provides an Ag-based alloy reflective film or semi-transmissive reflective film of an optical information recording medium having high reflectivity and excellent in the wet heat resistance and the light fastness. The invention relates to a reflective film or a semi-transmissive reflective film of an optical information recording medium comprising an Ag-based alloy comprising Hf in an amount of 0.05 to 0.8 atomic %.

### TECHNICAL FIELD

The present invention concerns a reflective film and a semi-transmissive reflective film comprising an Ag-based alloy of an optical information recording medium (particularly, for DVD, Blu-ray Disk (BD), and HD DVD), a sputtering target for manufacturing them, as well as an optical information recording medium having the reflective film and/or semi-transmissive reflective film described above.

### BACKGROUND ART

For the reflective film or the semi-transmissive reflective film (hereinafter sometimes referred to collectively as “(semi-transmissive) reflective film”) of an optical information medium, Au, Al, Ag or an alloy thereof has been used generally with a view point of the reflectivity and durability (particularly, durability to high temperature and high humidity).

Since an Au type (semi-transmissive) reflective film is excellent in the durability, an optical information recording medium using the same suffers from less aging deterioration. However, the material cost of the Au type (semi-transmissive) reflective film is expensive and, further, has low reflectivity to a purple-violet laser light (wavelength: 405 nm) used for DVD (BD and HD DVD) in the next generation.

Since the Al type (semi-transmissive) reflective film is inexpensive in view of the material cost, the production cost for the optical information recording medium can be decreased. Further, the Al type (semi-transmissive) reflective film has high reflectivity to the blue-violet laser light. However, the Al type (semi-transmissive) reflective film has low durability.

The Ag type (semi-transmissive) reflective film is less expensive in view of the material cost compared with the Au type (semi-transmissive) reflective film and has higher reflectivity to the blue-purple laser light. However, while the Ag type (semi-transmissive) reflective film is more excellent than the Al type (semi-transmissive) reflective film in view of the durability, it is not comparable with the Au type (semi-transmissive) reflective film. Then, various techniques have been proposed so far for improving the durability of the Ag type (semi-transmissive) reflective film.

For example, Patent Document 1 proposes a silver alloy used for a reflective film comprising a rare earth element as a first additive element and improved with sulfidation resistance, humidity resistance, and heat resistance. Further, the Patent Document 1 describes gallium, platinum, palladium, etc. as a second additive element having an effect of improving the sulfidation resistance, the humidity resistance, and the heat resistance of the silver alloy, together with the first additive element (rare earth element).

However, a thin film comprising the silver alloy shown in the Patent Document 1 has a reflectivity at an identical with or somewhat lower level when compared with the thin film comprising pure silver and the silver alloy thin film, while showing high reflectivity, cannot improve the sulfidation resistance, the humidity resistance, and the heat resistance as other characteristics.

Further, in the Patent Document 1, only the silver alloy used as the reflective film is disclosed, and the semi-transmissive reflective films have not been studied at all. As a proof, only the silver alloy at a film thickness of 1200 Å (120 nm) is disclosed in the examples of the Patent Document 1 and it is considered that an additional consideration is necessary for the application thereof to the semi-transmissive reflective film.

[Patent Document 1] Pamphlet of WO2005/056850

### DISCLOSURE OF THE INVENTION

### Subject to be Solved by the Invention

The present invention has been achieved in view of the situation described above and the object thereof is to provide an Ag-based alloy (semi-transmissive) reflective film of an optical information recording medium having a high reflectivity and an excellent durability to high temperature and high humidity (hereinafter simply referred to as “wet heat resistance”), and light fastness, an optical information recording medium having the (semi-transmissive) reflective film, and an Ag-based alloy sputtering target used for the manufacture of the (semi-transmissive) reflective film.

### Means for Solving the Subject

Summary of the invention is shown below.

(1) A reflective film or a semi-transmissive reflective film of an optical information recording medium comprising an Ag-based alloy comprising Hf in an amount of 0.05 to 0.8 atomic %.
(2) A reflective film or a semi-transmissive reflective film of an optical information recording medium described in (1) above wherein the Ag-based alloy further comprises at least one element selected from the group consisting of Ce, La, Pr, Nd, and Sm in an amount of 0.01 to 0.8 atomic % in total.

By the incorporation of Ce, etc. in addition to Hf, the wet heat resistance and the light fastness of the (semi-transmissive) reflective film can be improved further.

(3) A semi-transmissive reflective film of an optical information recording medium described in (1) or (2) above wherein the film thickness is from 5 to 30 nm.
(4) An optical information recording medium having at least one of the reflective film described in (1) or (2) above, or the semi-transmissive reflective film described in any one of (1) to (3) described above.
(5) An Ag-based alloy sputtering target used for the manufacture of a reflective film or a semi-transmissive reflective film of an optical information recording medium, comprising an Ag-based alloy comprising Hf in an amount of 0.05 to 0.8 atomic %.
(6) An Ag-based alloy sputtering target described in (5) above, wherein the Ag-based alloy further comprises at least one element selected from the group consisting of Ce, La, Pr, Nd, and Sm in an amount of 0.01 to 0.8 atomic % in total.

### EFFECT OF THE INVENTION

According to the invention, a high reflectivity can be obtained and the wet heat resistance and the light fastness of the Ag-based alloy (semi-transmissive) reflective film can be improved by the incorporation of a predetermined amount of Hf.

### BEST MODE FOR CARRYING OUT THE INVENTION

When the Ag-based alloy (semi-transmissive) reflective film is left under a circumstance at a high temperature and at a high humidity and under photo-irradiation for a long time, the reflectivity and the brightness thereof are deteriorated due to agglomeration of Ag and the signal quality of the optical information recording medium having the reflective film is deteriorated. For suppressing the agglomeration and improving the wet heat resistance and the light fastness, an alloying element may be added. However, addition of the alloying element tends to deteriorate the reflectivity of the (semi-transmissive) reflective film.

Then, as a result of an earnest study made by the present inventors, et. al., it has been found that a reflectivity higher than that of pure Ag can be attained, as well as the wet heat resistance and the light fastness can be improved sufficiently, particularly, by incorporating a predetermined amount of Hf among alloying elements in an Ag-based alloy that forms the (semi-transmissive) reflective film.

The effect cannot be provided sufficiently when the amount of Hf is insufficient. Accordingly, it is necessary that the Hf amount in the Ag-based alloy is 0.05 atomic % or more (preferably, 0.1 atomic % or more). On the other hand, when the amount of Hf is excessive, the reflectivity of the (semi-transmissive) reflective film is lowered. Accordingly, the amount of Hf in the Ag-based alloy is defined as 0.8 atomic % or less (preferably, 0.6 atomic % or less and, more preferably, 0.5 atomic % or less).

When at least one of Ce, La, Pr, Nd, and Sm is used together in addition to Hf, the wet heat resistance and the light fastness of the Ag-based alloy (semi-transmissive) reflective film can be improved further while maintaining the high reflectivity. The effect can be provided sufficiently by incorporating Ce, etc. by a predetermined amount or more. Accordingly, it is preferred that the total amount for at least one of Ce, La, Pr, Nd, and Sm in the Ag-based alloy is 0.01 atomic % or more (more preferably, 0.05 atomic % or more). However, when the amount of Ce, etc. is excessive, the reflectivity of the (semi-transmissive) reflective film tends to be lowered. Accordingly, the total amount of at least one of Ce, La, Pr, Nd, and Sm in the Ag-based alloy is preferably 0.8 atomic % or less and, more preferably, 0.6 atomic % or less.

The composition chemical for ingredients of the Ag-based alloy of the (semi-transmissive) reflective film of the invention is as has been described above and the balance thereof essentially consists of Ag. However, the Ag-based alloy may comprise inevitable impurities intruded during manufacture of the (semi-transmissive) reflective film, etc. (for example, oxygen (O), carbon (C), hydrogen (H), nitrogen (N), argon (Ar), iron (Fe), silicon (Si), etc.) and each of the elements can be intruded by about 200 ppm or less but the range is not restrictive.

As has been described above, the Ag-based alloy (semi-transmissive) reflective film of the invention shows high reflectivity and excellent wet heat resistance and light fastness. Therefore, this is used suitably as a reflective film and/or a semi-transmissive reflective film of DVD (for example, DVD-ROM, DVD-R, DVD+R, DVD-RW, DVD+RW, DVD-RAM), BD (for example, BD-ROM, BD-R, BD-RE) and HD DVD (for example, HD DVD-ROM, HD DVD-R, HD DVD-RE) as optical information recording media. Particularly, the reflective film of the invention is used more preferably for a DVD that reads information by using a red laser light (wavelength: 650 nm) and the semi-transmissive reflective film of the invention is used more preferably for a BD or HD DVD that reads information by using a blue-purple laser light (wavelength: 405 nm).

The reflective film of the optical information recording medium (optical disk) in the invention means a reflective film for single layer recording that conducts recording only on one disk surface, or a film used as a reflective film most remote from an optical pick-up when an optical disk is set to a recording/reproducing apparatus for multi-layer recording. The transmittance of the reflective film is about 0%. Further, the film thickness of the reflective film is usually from 15 to 250 nm. The thickness of the reflective film is preferably from 50 to 250 nm in a case of use for single layer DVD-R, DVR+R, or HD DVD-R, preferably, from 50 to 200 nm in a case of use for a single layer DVD+RW, DVD-RW, BD-RE, or BD-R and, preferably, from 15 to 50 nm in a case of use for a BD-ROM.

The semi-transmissive reflective film of the optical information recording medium (optical disk) in the invention means a film used as a reflective film of a medium that conducts two or more multi-layer recording on one disk surface (excluding a reflective film most remote from an optical pick-up when the optical disk is set to recording/reproducing apparatus). Further, the thickness of the semi-transmissive reflective film is usually from 5 to 30 nm. The thickness of the semi-transmissive reflective film is, preferably, from 5 to 15 nm in a case of use for a semi-transmissive reflective film of 2-layered DVD-ROM and, preferably, from 10 to 30 nm in a case of use for a 2-layered disk of DVD-R, DVD+R, or HD DVD-R.

The invention also includes an optical information recording medium having the (semi-transmissive) reflective film described above. The optical information recording medium of the invention has no particular restriction for the constitution other than that of the (semi-transmissive) reflective film, and any constitution known in the relevant field can be adopted. For example, in a case of using the semi-transmissive reflective film of the invention to the optical information recording medium, Al, Ag or an alloy thereof can be used for the reflective film of the optical information recording medium. For example, in a single layered DVD-R, DVD+R, or HD DVD-R, a structure of using a dye layer as a recording layer and stacking the dye layer and the reflective film in adjacent with each other such that the dye layer situates on this side in view of the incident surface of a reproducing laser light can be adopted. Further, in BD-ROM, an UV-ray curable resin or a polycarbonate can be used for the material of a transparent protective layer having a thickness of 0.1 μm formed on the incident side of a reproducing laser light. In BD-R, the recording layer includes those comprising a metal oxide, a metal nitride, or a dye and, as a protective layer formed above and below the recoding layer, a protective layer comprising ZnS, SiO₂, or a mixture thereof, or a protective layer comprising Al₂O₃ is used. For example, in a single layered DVD+RW, BD-RE, or HD DVD-RW, a chalcogen compound which is a phase changing material, for example, Ge—Sb—Te, Ag—In—Sb—Te, etc. can be used as the material for a recording layer.

While the Ag-based alloy (semi-transmissive) reflective film of the invention can be deposited to a substrate by sputtering, vacuum deposition, or ion plating to the substrate, it is preferably deposited by sputtering. Since a (semi-transmissive) reflective film more excellent in the alloying element distribution and the in-plane uniformess of the film thickness can be obtained by sputtering compared with films deposited by other methods, an optical information recording medium of high performance and high reliability can be manufactured.

In the sputtering described above, for forming the (semi-transmissive) reflective film of the invention an Ag-based alloy sputtering target;

(1) comprising an Ag-based alloy comprising Hf in an amount of 0.05 to 0.8 atomic % (preferably, 0.1 atomic % or more and, preferably, 0.6 atomic % or less and, more preferably, 0.5 atomic % or less) or
(2) comprising an Ag-based alloy comprising Hf in the amount described above and further comprising at least one element selected from the group consisting of Ce, La, Pr, Nd, and Sm in an amount of 0.01 to 0.8 atomic % (preferably, from 0.05 to 0.6 atomic %) in total; and

having identical ingredients and composition with the (semi-transmissive) reflective film having desired ingredients and composition is used preferably, since a (semi-transmissive) reflective film of desired ingredients and composition can be formed thereby with no compositional deviation.

The composition for chemical ingredients of the Ag-based alloy of the sputtering target of the invention is as has been described above and the balance thereof essentially consists of Ag. However, the Ag-based alloy may also comprise inevitable impurities intruded during manufacture of the sputtering target, etc. (for example, nitrogen (N), oxygen (O), carbon (C), hydrogen (H), argon (Ar), iron (Fe), silicon (Si), etc.) and each of the elements can be intruded by about 200 ppm or less but the range is not restrictive.

The Ag-based alloy sputtering target of the invention can be manufactured by a method such as a vacuum melting-casting method, a powder sintering method, or a spray forming method, etc. Among them, it is particularly preferred to manufacture by the vacuum melting-casting method. The Ag-based alloy sputtering target manufactured by the vacuum melting-casting method has less content of impurity ingredients such as nitrogen and oxygen compared with that manufactured by other methods, and a (semi-transmissive) reflective film of high performance and high reliability, and an optical information recording medium having the same can be manufactured from the sputtering target.

### EXAMPLE

The present invention is to be described more specifically with reference to examples but it will be apparent that the invention is not limited by the following examples and can be practiced with appropriate modifications within a range conforming to the purport described above and to be described later and any of them is encompassed within the technical range of the invention.

### (Manufacture of an Ag-Based Alloy Thin Film)

A pure Ag thin film and an Ag-based alloy thin film shown in the following Table 1 (each 15 nm thickness) were deposited over a polycarbonate resin substrate (0.6 mm thickness×12 cm diameter) by DC magnetron sputtering under the following sputtering conditions. In the film deposition, two targets each of 4 inch diameter (pure Ag target and target in which various alloying element chips were disposed to the pure Ag target) were sputtered simultaneously, the sputtering power was controlled to 500 W in total, and the addition amount was controlled by the ratio of the power. In this example, two targets were used as described above and film deposition was conducted by changing the power ratio while simulating film deposition using a target of identical ingredients and composition with that for each of the Ag-based alloy films for depositing Ag-based alloy films of various ingredients and compositions. The compositions of the formed Ag-based alloy thin films were determined by inductively coupled plasma (ICP) mass spectrometry.

### (Sputtering Conditions)

Sputtering apparatus: CS-200 manufactured by Ulvac Inc.

Ar gas pressure: 3 m Torr

Zr gas flow rate: 29 sccm

Substrate rotational speed: 30 rpm

Substrate temperature: room temperature

### (Measurement for Reflectivity)

The absolute reflectivity of the pure Ag thin film and the Ag-based alloy thin film described above were measured by using V-570 visible-UV spectrophotometer manufactured by JASCO Corporation. The wavelength for the measurement of the absolute reflectivity was 405 nm (wavelength of a blue-purple laser light used for BD or HD DVD) and 650 nm (wavelength of a red laser light used for DVD).

The result is shown in the following Table 1. The reflectivity was evaluated as good (A) for 28% or more and poor (B) for at less than 28% at a wavelength of 405 nm (blue-purple laser light) and evaluated as good (A) for 56.0% or more and as poor (B) for less than 56.0% at a wavelength of 650 nm (red laser light).

TABLE 1

| | Composition of thin | Reflectivity (%) | | Reflectivity (%) | |
|---|---|---|---|---|---|
| | film (unit: atomic % | Wavelength | | Wavelength | |
| No. | alloy residue: Ag) | 405 nm | Evaluation | 650 nm | Evaluation |
| 1 | Pure Ag | 28.9 | A | 56.1 | A |
| 2 | Ag-1.0% Ce | 26.0 | B | 53.4 | B |
| 3 | A-0.1% Hf | 29.2 | A | 58.8 | A |
| 4 | Ag-0.2% Hf | 30.3 | A | 60.0 | A |
| 5 | Ag-0.4% Hf | 31.0 | A | 61.1 | A |
| 6 | Ag-1.0% Hf | 25.9 | B | 55.5 | B |
| 7 | Ag-0.1% Hf -0.1% Ce | 31.1 | A | 62.0 | A |
| 8 | Ag-0.1% Hf-0.3% Ce | 29.2 | A | 58.7 | A |
| 9 | Ag-0.1% Hf-0.5% Ce | 29.3 | A | 58.2 | A |
| 10 | Ag-0.1% Hf-0.1% La | 30.1 | A | 60.0 | A |
| 11 | Ag-0.1% Hf-0.2% La | 30.8 | A | 60.7 | A |
| 12 | Ag-0.1% Hf-0.5% La | 29.7 | A | 59.4 | A |
| 13 | Ag-0.1% Hf-0.1% Pr | 30.1 | A | 60.0 | A |
| 14 | Ag-0.1% Hf-0.3% Pr | 29.2 | A | 58.7 | A |
| 15 | Ag-0.1% Hf-0.5% Pr | 29.3 | A | 58.7 | A |
| 16 | Ag-0.1% Hf-0.2% Nd | 30.7 | A | 61.8 | A |
| 17 | Ag-0.1% Hf-0.3% Nd | 30.4 | A | 60.3 | A |
| 18 | Ag-0.1% Hf-0.5% Nd | 28.4 | A | 57.1 | A |
| 20 | Ag-0.1% Hf-0.2% Sm | 31.3 | A | 62.2 | A |
| 21 | Ag-0.1% Hf-0.5% Sm | 29.7 | A | 59.7 | A |

### (Evaluation for Wet Heat Resistance)

For Nos. 1 to 15 in Table 1 above, the wet heat resistance was also evaluated. The wet heat resistance was evaluated by measuring the change of the brightness of the pure Ag thin film and the Ag-based alloy thin films left in a high temperature and high humidity circumstance for a long time. Specifically, the thin films were left in a circumstance at a temperature of 80° C. and at a humidity of 85% RH for 96 hr, and the spectral reflectivities of the thin films before and after thereof (region for measuring wavelength: 380 to 780 nm) were measured. Then, based on the result of the measurement, the brightness Y of the xyY color representation type was calculated by using the following equation (1) to determine the change of the brightness (brightness after leaving−brightness before leaving).

[Equation 1]

Y=KmƒS(λ)R(λ) y̅(λ)dλ (1)

In the formula (I),
Y: brightness of the xyY color representation type
S(λ): spectral radiant flux distribution of light source
R(λ): spectral reflectivity of sample
y̅(λ): color matching function
Km: constant

The result described above is shown in the following Table 2. For the wet heat resistance, those showing the change of brightness of −8 or more were evaluated as good (A) and those showing the change of less than −8 were evaluated as poor (B).

TABLE 2

| | | Wet heat | |
|---|---|---|---|
| | Composition of thin | resistance | |
| | film (unit atomic % | (change of | |
| No. | alloy residue: Ag) | brightness) | Evaluation |
| 1 | Pure Ag | −12.5 | B |
| 2 | Ag—1.0% Ce | −0.2 | A |
| 3 | Ag—0.1% Hf | −5.0 | A |
| 4 | Ag—0.2% Hf | −2.9 | A |
| 5 | Ag—0.4% Hf | −3.0 | A |
| 6 | Ag—1.0% Hf | −4.0 | A |
| 7 | Ag—0.1% Hf—0.1% Ce | −2.2 | A |
| 8 | Ag—0.1% Hf—0.3% Ce | −1.9 | A |
| 9 | Ag—0.1% Hf—0.5% Ce | −1.6 | A |
| 10 | Ag—0.1% Hf—0.1% La | −1.4 | A |
| 11 | Ag—0.1% Hf—0.2% La | −1.3 | A |
| 12 | Ag—0.1% Hf—0.5% La | −1.2 | A |
| 13 | Ag—0.1% Hf—0.1% Pr | −1.6 | A |
| 14 | Ag—0.1% Hf—0.3% Pr | −0.8 | A |
| 15 | Ag—0.1% Hf—0.5% Pr | −1.1 | A |

### (Evaluation for Light Fastness)

For Nos. 1 to 6 in Table 1 described above, also the light fastness was further evaluated. The light fastness was evaluated by measuring the change of the brightness of the pure Ag thin film and the Ag-based alloy thin film left under the irradiation of a fluorescent lamp for a long time. Specifically, alight of a fluorescent lamp was irradiated to the thin films for 240 hr in a state of setting the color temperature of the fluorescent lamp to 6700 K and keeping the distance between the lower end of the fluorescent lamp and the surface of the thin film at 60 mm. The spectral reflectivity (region for measuring wavelength: 380 to 780 nm) of the thin film before and after thereof was measured. Then, based on the result of the measurement, the brightness Y of the xyY color representation type was calculated by using the formula (I) described above to determine the change of the brightness (brightness after leaving−brightness before leaving).

The result is shown in the following Table 3. The light fastness was evaluated as good (A) for those showing the change of the brightness of −2 or more and evaluated as poor (B) showing the change of less than −2.

TABLE 3

| | Composition of thin | Light fastness | |
|---|---|---|---|
| | film (unit atomic % | (change of | |
| No. | alloy residue: Ag) | brightness) | Evaluation |
| 1 | Pure Ag | −3.0 | B |
| 2 | Ag—1.0% Ce | −0.2 | A |
| 3 | Ag—0.1% Hf | −1.1 | A |
| 4 | Ag—0.2% Hf | −0.7 | A |
| 5 | Ag—0.4% Hf | −0.8 | A |
| 6 | Ag—1.0% Hf | −1.0 | A |

From the results shown in Tables 1 to 3 described above, it can be seen that the thin films comprising the Ag-based alloys comprising a predetermined amount of Hf show higher reflectivity than that of the pure Ag thin film, and are excellent in the wet heat resistance and the light fastness.

While the invention has been explained specifically with reference to specific embodiments, it will be apparent to a person skilled in the art that the invention can be changed or modified variously without departing from the spirit and the scope of the invention.

The present application is based on Japanese Patent Application filed on Feb. 8, 2008 (Japanese Patent Application No. 2008-029116), the contents of which are incorporated herein only for the reference.

### INDUSTRIAL APPLICABILITY

The present invention relates to a reflective film and a semi-transmissive reflective film comprising an Ag-based alloy of an optical information recording medium (particularly, DVD, Blu-ray Disk (BD) and HD DVD), and a sputtering target for manufacturing them, as well as an optical information recording medium having the reflective film and/or semi-transmissive reflective film. According to the invention, a high reflectivity can be attained and the wet heat resistance and the light fastness of the Ag-based alloy (semi-transmissive) reflective film can be improved by incorporating a predetermined amount of Hf in the Ag-based alloy.

1. A reflective film comprising an Ag-based alloy comprising Hf in an amount of 0.05 to 0.8 atomic %.

2. The reflective film according to claim 1, wherein the Ag-based alloy further comprises at least one element selected from the group consisting of Ce, La, Pr, Nd, and Sm.

3. The reflective film of an optical information recording medium according to claim 7, wherein the film thickness is from 5 to 30 nm.

4. An optical information recording medium comprising the reflective film according to claim 1.

5. An Ag-based alloy sputtering target comprising an Ag-based alloy comprising Hf in an amount of 0.05 to 0.8 atomic %.

6. An Ag-based alloy sputtering target according to claim 5, wherein the Ag-based alloy further comprises at least one element selected from the group consisting of Ce, La, Pr, Nd, and Sm in an amount of 0.01 to 0.8 atomic % in total.

7. The reflective film of claim 1, wherein the reflective film is semi-transmissive.

8. The reflective film of claim 7, wherein the film thickness is from 5 to 30 nm.

9. An optical information recording medium comprising the reflective film according to claim 7.

10. A method of manufacturing a reflective film comprising depositing the Ag-based alloy sputtering target of claim 5 on a substrate.

11. A method of manufacturing a semi-transmissive reflective film comprising depositing the Ag-based alloy sputtering target of claim 5 on a substrate.
